(19) United States
(12) Patent Application Publication
(10) Pub. No.: US 2026/0050038 A1
(43) Pub. Date: Feb. 19, 2026

(54) MODEL PARAMETER ESTIMATION DEVICE AND MODEL PARAMETER ESTIMATION METHOD

(71) Applicant: Mitsubishi Electric Corporation, Tokyo (JP)

(72) Inventor: Tomoki TAKEGAMI, Tokyo (JP)

(73) Assignee: Mitsubishi Electric Corporation, Tokyo (JP)

(21) Appl. No.: 19/101,616

(22) PCT Filed: Oct. 14, 2022
(86) PCT No.: PCT/JP2022/038310

§ 371 Date: Feb. 6, 2025

(51) Int. Cl. G01R 31/367; G01R 31/388; G01R 31/396

(52) U.S. Cl. CPC G01R 31/367; G01R 31/388; G01R 31/396

(57) ABSTRACT

This model parameter estimation device comprises a state quantity calculator to calculate state quantities indicating a state of a target system with respect to a measured value of an input on the basis of a state equation obtained by assigning values to nonlinear parameters for a model that represents the target system using the nonlinear parameters and linear parameters, and time-series data of the input and an output of the target system, a linear parameter estimator to estimate the linear parameters that minimize an error between the measured value of the output and an estimated value of the output calculated on the basis of the model, the state quantities, and the measured value of the input, and a nonlinear parameter updater to repeatedly update the values of the nonlinear parameters so as to make the minimized error to be small until a convergence condition is satisfied.

### TECHNICAL FIELD

The present application relates to a model parameter estimation device and a model parameter estimation method.

### BACKGROUND ART

In order to reduce environmental loads, stationary power storage systems for utilizing renewable energy have become widespread. In addition, electric vehicles such as an electric vehicle (EV), a hybrid electric vehicle (HEV), and a plug-in hybrid vehicle (PHV) have been put into practical use, and further, an electric aircraft and the like have been developed.

On the other hand, a storage battery such as a lithium-ion battery is used in these devices, but it is known that the storage battery deteriorates as it is used, and the performance decreases. Therefore, there is a demand for a model parameter estimation technique for modeling a storage battery with high accuracy in order to estimate a state of charge (SOC) with high accuracy, diagnose deterioration, predict a life, and the like for the storage battery.

Therefore, a model parameter estimation technique by a continuous-time system identification method based on an output error method has been proposed (for example, refer to Patent Document 1). Specifically, by applying a nonlinear optimization method to time-series data of currents and voltages during charging and discharging of a storage battery, model parameters are estimated so that an output voltage of a storage battery model constructed as a continuous-time system matches a measured voltage.

According to this method, by appropriately selecting initial values of the estimation, it is possible to estimate model parameters with high accuracy while nonlinearity of an open circuit voltage (OCV) characteristic is considered.

### PRIOR ART DOCUMENT

### Patent Document

Patent Document 1: Japanese Patent Application Laid-Open No. 2014-86313 (paragraphs 0017 to 0018, FIG. 1, paragraphs 0044 to 0045, FIG. 5)

### SUMMARY OF INVENTION

### Problems to be Solved by Invention

However, in the method proposed in Patent Document 1, it is necessary to set initial values of all parameters prior to estimation, but estimated values may diverge or converge to a local solution different from the true values depending on how the initial values are given. Therefore, it is essential to set the initial values based on prior information of a target system, making it difficult to apply the method to a system having little prior information.

The present application discloses a technique for solving the above-described problem, and an object thereof is to obtain a model parameter estimation device and a model parameter estimation method capable of estimating parameters with little information.

### Means for Solving the Problems

A model parameter estimation device disclosed in the present application includes a state quantity calculation unit to calculate state quantities indicating a state of a storage battery with respect to a measured value of a current on a basis of a state equation obtained by assigning values to nonlinear parameters for a state space model that represents the storage battery using the nonlinear parameters and linear parameters, and time-series data of each of measured values of the current and a terminal voltage of the storage battery, a linear parameter estimation unit to estimate the linear parameters that minimize an error between the measured value of the terminal voltage and an estimated value of the terminal voltage calculated on a basis of the state space model, the state quantities, and the measured value of the current, and a nonlinear parameter update unit to repeatedly update the values of the nonlinear parameters so as to make the minimized error to be small until a predetermined convergence condition is satisfied.

A model parameter estimation method disclosed in the present application includes a step of setting initial values of nonlinear parameters of a state space model that represents a storage battery using the nonlinear parameters and linear parameters, a state quantity calculation step of calculating state quantities indicating a state of the storage battery with respect to a measured value of a current on a basis of a state equation obtained by assigning values to the nonlinear parameters for the state space model, and time-series data of each of measured values of the current and a terminal voltage of the storage battery, a linear parameter estimation step of estimating the linear parameters that minimize an error between the measured value of the terminal voltage and an estimated value of the terminal voltage calculated on a basis of the state space model, the state quantities, and the measured value of the current, and a nonlinear parameter update step of updating the nonlinear parameters by repeatedly updating the values of the nonlinear parameters so as to make the minimized error to be small until a predetermined convergence condition is satisfied.

### Advantageous Effect of Invention

According to the model parameter estimation device or the model parameter estimation method disclosed in the present application, since the model parameters can be estimated by setting the initial values of only nonlinear parameters, it is possible to estimate the parameters with little information.

### BRIEF DESCRIPTION OF THE DRAWINGS

FIG. 1 is a block diagram for describing a configuration of a model parameter estimation device according to Embodiment 1.

FIG. 2 is a block diagram showing a hardware configuration example of a part that executes arithmetic processing of the model parameter estimation device according to Embodiment 1.

FIG. 3 is a diagram showing an equivalent circuit of a storage battery for which model parameters are to be estimated.

FIG. 4 is a diagram showing a Foster-type equivalent circuit as another model of a storage battery for which model parameters are to be estimated.

FIG. 5 is a flowchart showing an operation of the model parameter estimation device or a model parameter estimation method according to Embodiment 1.

FIG. 6 is a diagram in the form of a graph showing changes over time in measured values of voltages, measured values of currents, and estimated values of currents by a model when the model parameter estimation device or the model parameter estimation method according to Embodiment 1 is applied to a certain storage battery system.

FIG. 7 is a diagram in the form of a graph showing a relationship between electric quantity and an open circuit voltage as an OCV function estimated when the model parameter estimation device or the model parameter estimation method according to Embodiment 1 is applied to a certain storage battery system.

### MODE FOR CARRYING OUT INVENTION

### Embodiment 1

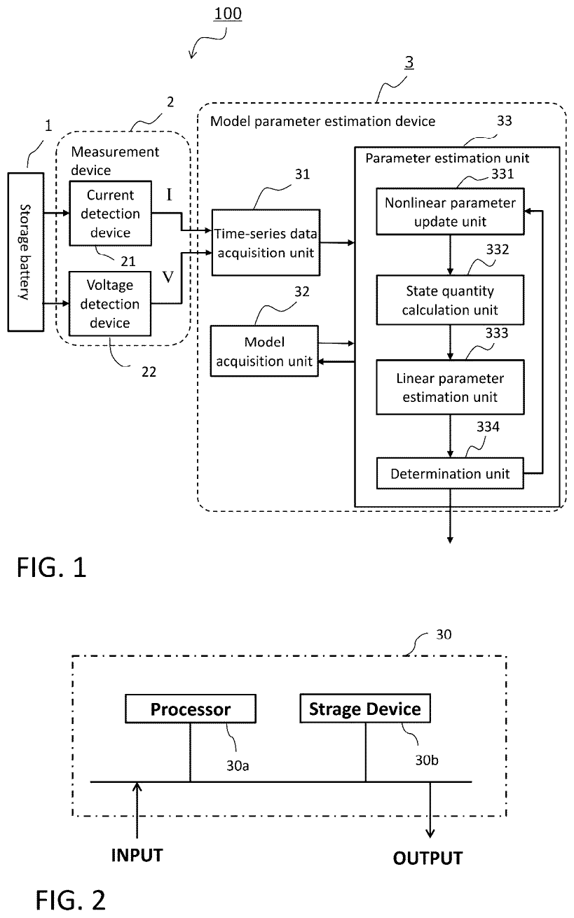

FIG. 1 to FIG. 7 are diagrams for describing a configuration and an operation of a model parameter estimation device and a model parameter estimation method according to Embodiment 1, FIG. 1 is a block diagram of a storage battery system that includes a storage battery being an estimation target and the model parameter estimation device for describing the configuration of the model parameter estimation device, and FIG. 2 is a block diagram showing a hardware configuration example of a part that executes arithmetic processing of the model parameter estimation device.

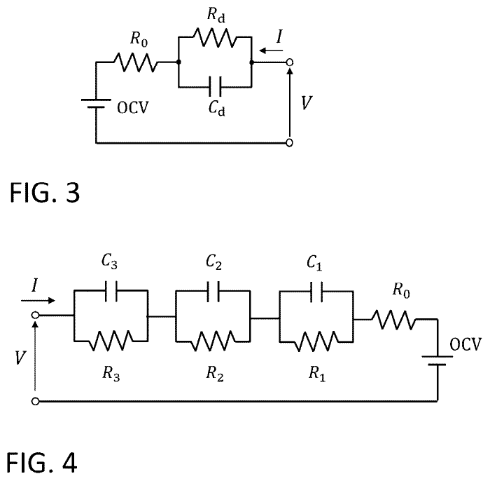

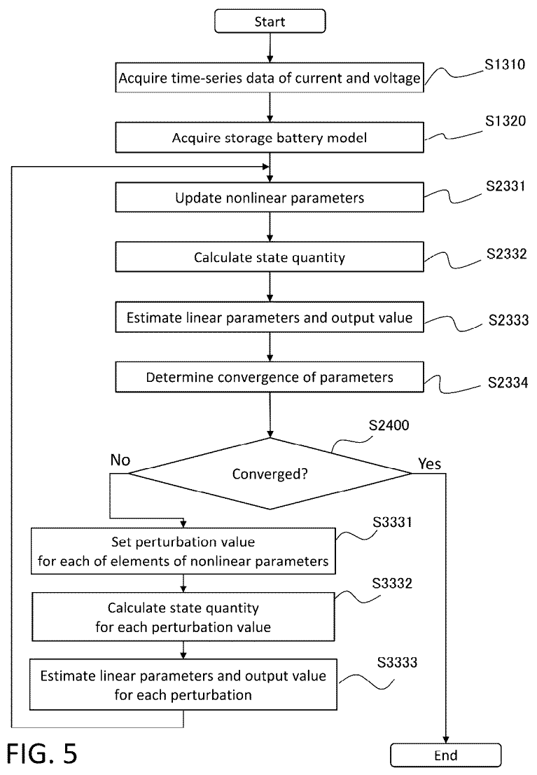

Further, FIG. 3 is a diagram showing an equivalent circuit in which a storage battery for which model parameters are to be estimated is represented by a DC component and a relaxation component of an overvoltage, and FIG. 4 is a diagram showing a Foster-type equivalent circuit in which multiple CR parallel elements are connected in series to represent a diffusion impedance as another model of a storage battery. FIG. 5 is a flowchart showing a model parameter estimation operation in the model parameter estimation device, that is, a model parameter estimation method.

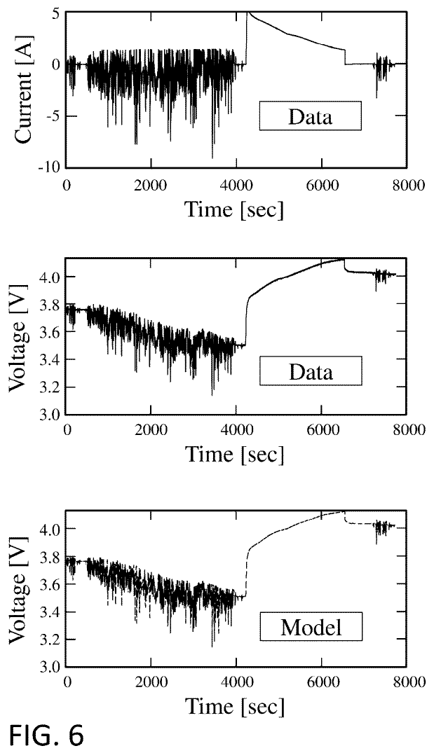

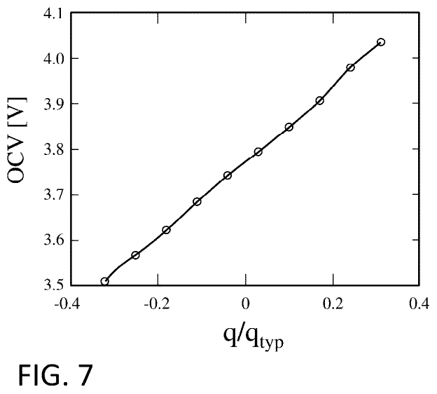

Further, FIG. 6 is a diagram in which three graphs showing respective changes over time in measured values of voltages of a storage battery, in measured values of currents of the storage battery, and in estimated values of currents by a model when the model parameter estimation device or the model parameter estimation method is applied to a certain storage battery system are vertically arranged, in which a horizontal axis indicates a common (synchronized) time, and a vertical axis indicates each of a measurement result of voltages, a measurement result of currents, and estimated values of currents. Further, FIG. 7 is diagram in the form of a graph showing an OCV function estimated at this time, in which the horizontal axis represents electric quantity standardized by a certain standard capacity and the vertical axis represents an open circuit voltage.

Hereinafter, the model parameter estimation device and the model parameter estimation method according to an embodiment of the present application will be described in detail with reference to the drawings as appropriate. Note that, in the drawings, the same reference numerals denote the same or corresponding parts.

As shown in FIG. 1, a model parameter estimation device 3 according to Embodiment 1 is provided in a storage battery system 100 including a storage battery 1 in order to diagnose the storage battery 1. Then, the model parameter estimation device is connected to a detection unit 2 including a current detection device 21 for detecting a current and a voltage detection device 22 for detecting a voltage, which are an output characteristic of the storage battery 1, and is configured to estimate model parameters of the storage battery 1.

The storage battery 1 is typically assumed to be a lithium-ion storage battery, but is not limited to the lithium-ion storage battery, and may be another type of storage battery such as a lead storage battery, a nickel-metal hydride storage battery, a nickel-cadmium storage battery, or an all-solid-state storage battery. In addition, the storage battery 1 to be diagnosed may be a storage battery module in which a plurality of cells are connected in any combination of series connection and parallel connection, in addition to a single-cell storage battery. In addition, the storage battery 1 may be a pack in which modules are further connected in any combination of series connection and parallel connection, or the like, and it is arbitrary which unit is regarded as a single storage battery 1.

The model parameter estimation device 3 includes a time-series data acquisition unit 31 that acquires time-series data of measured values from a current value I and a voltage value V detected by the detection unit 2, and a model acquisition unit 32 that acquires a storage battery model and sets initial values of nonlinear parameters to be described later. Furthermore, the model parameter estimation device includes a parameter estimation unit 33 that estimates model parameters from the time-series data acquired by the time-series data acquisition unit 31, the storage battery model set by the model acquisition unit 32, and the initial values of the nonlinear parameters 4. Note that, here, an example in which the model acquisition unit 32 sets the initial values has been described, but an initial value setting unit may be provided separately or in the parameter estimation unit 33 to set (or read) the initial values.

The parameter estimation unit 33 includes a nonlinear parameter update unit 331 that updates the nonlinear parameters ϕ, and a state quantity calculation unit 332 that calculates state quantities of the storage battery model on the basis of a state equation of the storage battery model when the nonlinear parameters ϕ are fixed. Furthermore, a linear parameter estimation unit 333 that estimates linear parameters ψ on the basis of the storage battery model and the state quantities, and a determination unit 334 that determines whether or not parameter estimation has converged on the basis of a convergence determination condition are provided.

As shown in FIG. 2, the model parameter estimation device 3 may be configured with a piece of hardware 30 including a processor 30a and a storage device 30b. Although not shown, the storage device 30b includes a volatile storage device such as a random access memory and a nonvolatile auxiliary storage device such as a flash memory. Further, an auxiliary storage device such as a hard disk may be provided instead of the flash memory. The processor 30a executes a program input from the storage device 30b. In this case, the program is input from the auxiliary storage device to the processor 30a via the volatile storage device. In addition, the processor 30a may output data such as a calculation result to the volatile storage device of the storage device 30b, or may store the data in the auxiliary storage device via the volatile storage device.

That is, each of functions of the units constituting the model parameter estimation device 3, for example, the functions of the model acquisition unit 32, the state quantity calculation unit 332, the linear parameter estimation unit 333, and the nonlinear parameter update unit 331, is implemented by software, firmware, or a combination thereof. The software and the firmware are written as programs and stored in the storage device 30b. The processor 30a reads a program stored in the storage device 30b and executes the program, thereby implementing the function of each unit of the model parameter estimation device 3.

### General Description of Technology of Present Application

Technical details of the model parameter estimation device 3 and the model parameter estimation method of the present application will first be described with a general problem setting in which the target is not limited to the storage battery. First, it is assumed that a state space model of a target system is expressed as Equation (1).

$$\{ \begin{matrix}\dot{x} = f ( x , u ; {ϕ}_{x} ) \\ y = \text{?} ( x , u \text{?} {ϕ}_{y} ) ψ\end{matrix} \qquad ( 1 )$$

$$\text{?} \text{indicates text missing or illegible when filed}$$

Here, \dot{x} is a vector representing state quantities, u is an input, y is an output, and each of f and g is a certain nonlinear vector-valued function. Further, ϕₓ and ϕ_{y} are nonlinear parameter vectors in the state equation and the output equation, respectively, and V is a linear parameter vector.

What is desired to be solved here is to obtain a parameter θ that minimizes an evaluation function J(θ) based on the sum of squares of an error c between an output ŷ (estimated value) and a measured value y in the model shown in Equation (2) when measured values of time-series input/output data {u(tₖ)|k=0, . . . , N} and {y(tₖ) k=0, . . . , N} at times {tₖ| k=0, . . . , N} arbitrarily sampled at equal intervals or unequal intervals are given.

$${J ( θ ) = \frac{1}{N + 1} \text{?} ( {t}_{k} ) = \frac{1}{N + 1} \text{?} ( {t}_{k} \text{?} θ ) - y ( {t}_{k} ) )}^{2} \qquad ( 2 )$$

$$\text{?} \text{indicates text missing or illegible when filed}$$

Here, θ is a vector in which the linear parameters ψ and the nonlinear parameters ϕ are arranged, and is defined as θ:=[ϕ^{T}, ψ^{T}]^{T} with respect to ψ: =[ψₓ^{T}, ψ_{y}^{T}]^{T}.

Since this is a nonlinear optimization problem, it is possible to obtain a local optimal solution by a known nonlinear optimization method. For example, it is possible to use a Gauss-Newton method, a Levenberg-Marquardt method, or the like based on a gradient with respect to a parameter of the evaluation function or a gradient with respect to a parameter of the estimation output ŷ(tₖ, θ). Further, it is also possible to use a gradient-free method, that is, a method such as a Nelder-Mead method that is not based on gradient information, and there is no limitation on the specific method of nonlinear optimization.

In order to determine the gradient with respect to a parameter, a method based on calculation of a sensitivity equation as described in Patent Literature 1 can be used. Further, a gradient approximation method using a one-sided difference, a two-sided difference, or the like may be used, or an adjoint method by introducing an adjoint variable may be used.

Although Equation (1) describes a continuous-time state space model, the target system may be considered in discrete time. At this time, the state space model is described as in Equation (3).

$$\{ \begin{matrix}{x}_{k + 1} = {f}_{d} ( {x}_{k} , {u}_{k} ; \text{?} ) \\ {y}_{k} = {g}_{d}^{T} ( {x}_{k} , {u}_{k} ; {ϕ}_{y} ) ψ\end{matrix} \qquad ( 3 )$$

$$\text{?} \text{indicates text missing or illegible when filed}$$

Here, xₖ is a vector representing the state quantities at time k, uₖ and yₖ are the input and output, respectively, at time k, and each of f_{d} and g_{d} is a certain nonlinear vector-valued function. In order to convert a continuous-time system into a discrete-time system, a known method such as zero-order hold or first-order hold can be used.

On the other hand, when a continuous-time system is handled as it is, it is possible to calculate state quantities at an arbitrary time from input time-series data by applying a numerical solution of a known differential equation to an original state equation. The Euler method or the Runge-Kutta method may be typically used as a numerical solution method of the differential equation.

However, a general problem with an output error method dealing with a nonlinear optimization problem is that a parameter estimation value has an initial value dependence. Therefore, as described in the background art, there is a problem that a global optimal solution cannot be obtained unless the initial values of the estimation parameters are appropriately set. Therefore, attention is focused on the structure of the state space model of Equation (1), and it is considered to reduce the initial value dependency. First, when outputs of the model are arranged vertically according to the time series, Equation (4) is obtained.

$$[ \begin{matrix}\hat{y} ( {t}_{0} , θ ) \\ ⋮ \\ \hat{y} ( {t}_{N} , θ )\end{matrix} ] = [ \begin{matrix}{g}^{T} ( x ( {t}_{0} , \text{?} ) , u ( {t}_{0} ) ; {ϕ}_{y} \\ ⋮ \\ {g}^{T} ( x ( {t}_{N} , \text{?} ) , u ( {t}_{N} ) ; {ϕ}_{y}\end{matrix} ] ψ ↔ \hat{Y} ( ϕ , ψ ) = G ( ϕ ) ψ \qquad ( 4 )$$

$$\text{?} \text{indicates text missing or illegible when filed}$$

That is, the linear parameters ψ and the nonlinear parameters 4 can be expressed separately. At this time, a relational equation of Equation (5) holds for an output vector Y:=[y(t₀) . . . y(t_{N})]^{T} and an error vector E:=[ε(t₀), . . . , ε(t_{N})]^{T}.

$$Y = G ( ϕ ) ψ + E \qquad ( 5 )$$

Therefore, when the nonlinear parameters ϕ in Equation (5) are fixed, a linear least squares solution of the linear parameters ψ is obtained as in Equation (6) by the linear least squares method.

$$Ψ ( ϕ ) = {( {G}^{T} ( ϕ ) G ( ϕ ) )}^{- 1} {G}^{T} ( ϕ ) Y \qquad ( 6 )$$

Using the linear least squares solution of Equation (6), the problem to be solved is converted into a problem P2 of Equation (8), whereas the original optimization problem is a problem P1 of Equation (7).

$$P 1 : \text{?} {‖ Y - G ( ϕ ) ψ ‖}^{2} \qquad ( 7 )$$

$${{P 2 : \text{?} ‖ Y - G ( ϕ ) {G}^{T} ( ϕ ) G ( ϕ ) )}^{- 1} {G}^{T} ( ϕ ) γ ‖}^{2} \qquad ( 8 )$$

$$\text{?} \text{indicates text missing or illegible when filed}$$

That is, the problem P1 that originally needs to estimate all of the linear parameters V and the nonlinear parameters ϕ is converted into an estimation problem (problem P2) of only the nonlinear parameters ϕ. If the solution of the nonlinear parameters ϕ of the problem P2 is obtained (can be fixed), the solution of the linear parameters ψ is also immediately obtained by substituting the solution into Equation (6).

Note that since the problem P2 is also a nonlinear optimization problem, various known nonlinear optimization methods as described above can be used as in the case of solving the problem P1. When the problem P1 is converted into the problem P2, the estimation parameters are only the nonlinear parameters ϕ, and thus the following advantage is obtained.

First, the initial value dependence can be reduced. In the case of solving the original problem P1, it is necessary to set the initial values of all of the linear parameters y and the nonlinear parameters ϕ, whereas in the problem P2, the linear parameters V are determined as the linear least squares solution without initial values. Therefore, the problem can be solved by setting only the initial values of the nonlinear parameters ϕ. Therefore, the problem in estimating the true values of the parameters is made simpler.

Second, in the application of many nonlinear optimization methods, the amount of computation is reduced. For example, in the case of using a technique that uses gradient information with respect to the parameters of the model output, the sizes of the gradient vector, the Jacobian matrix, or the like are reduced by the extent that the gradient information of the linear parameters y is unnecessary. In addition, as another point of view, it is expected that the number of times of repeated calculation until the parameters converge can be reduced by the reduction of the number of estimation parameters.

Third, numerical stability is improved. In general, when an order of magnitude of a value is greatly different between estimation parameters, a problem such as a cancellation of significant digits is likely to occur. Therefore, it is expected that such a problem is less likely to occur by reducing the number of estimation parameters.

Next, a specific method for obtaining a solution will be described separately for a case where the linear parameters p include a linear equality constraint and a case where the linear parameters ψ include a linear equality constraint and a linear inequality constraint.

### <1: When Linear Parameters Include Linear Equality Constraint>

When the linear parameters ψ include a linear equality constraint, an equality constrained least squares problem of the linear parameters T is formulated as a problem P3 in Equation (9).

$$P 3 : \text{?} {‖ Y - G ( ϕ ) ψ ‖}^{2} \qquad ( 9 )$$

$$subject to {C}_{eq} ψ = {d}_{eq}$$

$$\text{?} \text{indicates text missing or illegible when filed}$$

Here, C_{eq} and d_{eq} are a matrix and a vector, respectively, describing a linear equality constraint on the linear parameters ty. In order to solve the problem P3 on the basis of the same idea as described above, when a sub-problem SP3 of the problem P3 is considered with respect to G=G(ϕ) in which the nonlinear parameters ϕ are fixed to certain values, Equation (10) is obtained.

$$SP 3 : {min}_{ψ} {‖ Y - G ψ ‖}^{2} \qquad ( 10 )$$

$$subject to {C}_{eq} ψ = {d}_{eq}$$

Since the sub-problem SP3 is an equality constrained linear least squares problem, it can be solved with the method of Lagrange multiplier. To be more specific, the sub-problem SP3 is to find w that minimizes an evaluation function L shown in Equation (11) using the Lagrange multiplier vector L.

$$L ( ψ ) = \frac{1}{2} {‖ Y - G ψ ‖}^{2} + {λ}^{T} ( {C}_{eq} ψ - {d}_{eq} ) \qquad ( 11 )$$

Then, when a case at which the gradients of the evaluation function L with respect to ϕ and λ become 0 is considered, Equation (12) is obtained.

$$\frac{\partial L}{\partial ψ} = {G}^{T} G ψ - {G}^{T} y + {C}_{eq}^{T} λ = 0 \qquad ( 12 )$$

$$\frac{\partial L}{\partial λ} = {C}_{eq} ψ - {d}_{eq} = 0$$

In summary, Equation (13) is obtained, and a solution can be immediately obtained.

$$[ \begin{matrix}{G}^{T} G & {C}_{eq}^{T} \\ {C}_{eq} & 0\end{matrix} ] [ \begin{matrix}ψ \\ λ\end{matrix} ] = [ \begin{matrix}{G}^{T} y \\ {d}_{eq}\end{matrix} ] ↔ [ \begin{matrix}ψ \\ λ\end{matrix} ] = {[ \begin{matrix}{G}^{T} G & {C}_{eq}^{T} \\ {C}_{eq} & 0\end{matrix} ]}^{- 1} [ \begin{matrix}{G}^{T} y \\ {d}_{eq}\end{matrix} ] \qquad ( 13 )$$

Therefore, in order to solve the problem P3, update of the nonlinear parameters by the nonlinear optimization method and calculation of the linear parameters by the method of Lagrange multiplier may be alternately repeated.

<2: Case where Linear Parameter Includes Linear Equality Constraint and Linear Inequality Constraint>

When the linear parameters include the linear equality constraint and the linear inequality constraint, the inequality constrained least squares problem for the linear parameters is formulated as a problem P4 in Equation (14).

$$P 4 : \text{?} {‖ Y - \text{?} ( ϕ ) ψ ‖}^{2} \qquad ( 14 )$$

$$subject to {C}_{eq} ψ = {d}_{eq}$$

$${C}_{ineq} ψ \leq {d}_{ineq}$$

$$\text{?} \text{indicates text missing or illegible when filed}$$

Here, C_{ineq} and d_{ineq} are a matrix and a vector, respectively, describing the linear inequality constraint on the linear parameters V. When a sub-problem SP4 of the problem P4 is considered in the same manner as in the case of the problem P3, Equation (15) is obtained.

$$SP 4 : {min}_{ψ} {‖ Y - G ψ ‖}^{2} \qquad ( 15 )$$

$$subject to {C}_{eq} ψ = {d}_{eq}$$

$${C}_{ineq} ψ \leq {d}_{ineq}$$

As a method of solving the sub-problem SP4, an interior point method, a sequential quadratic programming method, or the like can be used. In this case, iterative calculation is required, but since the sub-problem SP4 is a convex optimization problem, a global optimal solution is obtained. As a matter of course, since the sub-problem SP3 is included in the sub-problem SP4, it is possible to apply such a solution method by the iterative calculation to the sub-problem SP3. Therefore, in order to solve the problem P4, update of the nonlinear parameters by the nonlinear optimization method and the calculation of the linear parameters by the solution method of the convex optimization problem should be repeated.

Now, a specific application method of the nonlinear optimization method to the problem P1, the problem P3, and the problem P4 will be described with the problem P4 as a target. Note that, since the problem P1 and the problem P3 are included in the problem P4, it is sufficient to describe the problem P4 as the target. In fact, the problem P1 is a special case where there are no inequality and equality constraints in the problem P4. Further, the problem P3 is also a special case where there is no inequality constraint in the problem P4.

When an optimal solution of the linear parameters ψ with respect to certain nonlinear parameters ϕ in the sub-problem SP4 is ψ=ψ*(ϕ), an evaluation function to be minimized in the problem P4 is Equation (16).

$$\begin{matrix}L ( ϕ ) = \text{?} {( y ( {t}_{k} ) - \hat{y} ( \text{?} , ϕ , \text{?} ( ϕ ) ) )}^{2} \\ = \text{?} {( y ( {t}_{k} ) - \text{?} ( x ( {t}_{k} , \text{?} ) , u ( {t}_{k} ) ; {ϕ}_{y} ) \text{?} ( ϕ ) )}^{2} \\ = {‖ \text{?} - G ( ϕ ) \text{?} ( ϕ ) ‖}^{2}\end{matrix} \qquad ( 16 )$$

$$\text{?} \text{indicates text missing or illegible when filed}$$

Since ψ*(ϕ) can be obtained by solving the sub-problem SP4 by the method described above, it is only necessary to find the nonlinear parameters ϕ that minimize L(ϕ) in order to solve the problem P4. Hereinafter, a steepest descent method, which is a type of gradient method, a Gauss-Newton method, and a Nelder-Mead method, which is one of the gradient-free methods, will be described in order as the nonlinear optimization method.

### <Steepest Descent Method>

When the steepest descent method is used, an update equation of the nonlinear parameters ϕ is Equation (17).

$${ϕ}^{ℓ + 1} = {ϕ}^{ℓ} - α [ \begin{matrix}\frac{\partial L ( {ϕ}^{ℓ} )}{\partial {ϕ}_{1}} \\ ⋮ \\ \frac{\partial L ( {ϕ}^{ℓ} )}{\partial \text{?}}\end{matrix} ] \qquad ( 17 )$$

$$\text{?} \text{indicates text missing or illegible when filed}$$

Here, α is a predetermined positive value, and may be determined by a line search or the like for each update.

When it is difficult to directly obtain the gradient, a value such as a one-sided difference or a two-sided difference can be used as the gradient approximate value. For example, in the one-sided difference, the partial differential can be approximately calculated as in Equation (18) by perturbing ϕⱼ by a sufficiently small Δⱼ.

$$\frac{\partial L ( ϕ )}{\partial {ϕ}_{j}} \text{?} \frac{L ( ϕ + {Δ}_{j} {e}_{j} ) - L ( ϕ )}{{Δ}_{j}} \qquad ( 18 )$$

$$\text{?} \text{indicates text missing or illegible when filed}$$

Here, eⱼ is a unit vector having the same length as the nonlinear parameters ϕ and having only the j-th element being equal to 1. That is, ϕ+Δⱼeⱼ is a perturbation value obtained by perturbing only the j-th element of the nonlinear parameters ϕ. At this time, an update equation of the nonlinear parameters ϕ is Equation (19).

$${ϕ}^{ℓ + 1} = {ϕ}^{ℓ} - α [ \begin{matrix}\frac{L ( {ϕ}^{ℓ} + {Δ}_{1} {e}_{1} ) - L ( {ϕ}^{ℓ} )}{{Δ}_{1}} \\ ⋮ \\ \frac{L ( {ϕ}^{ℓ} + {Δ}_{{n}_{ϕ}} {e}_{{n}_{ϕ}} ) - L ( {ϕ}^{ℓ} )}{{Δ}_{{n}_{ϕ}}}\end{matrix} ] \qquad ( 19 )$$

Note that, in the calculation of the evaluation function L, it is necessary to calculate the state quantities for each value of the nonlinear parameters ϕ, estimate the linear parameters V, and calculate an output estimation value.

### <Gauss-Newton Method>

An update equation of the Gauss-Newton method is Equation (20), where Λ(ψ) is expressed by Equation (21), and ∂ŷ(tₖ, ϕ, ψ*(ϕ))/∂ϕⱼ is a sensitivity function, that is, a partial differential of the output estimation value with respect to a certain nonlinear parameter ϕⱼ.

$${ϕ}^{ℓ + 1} = {ϕ}^{ℓ} - {[ {Λ}^{T} ( {ϕ}^{ℓ} ) Λ ( {ϕ}^{ℓ} ) ]}^{- 1} {Λ}^{T} ( {ϕ}^{ℓ} ) \{ Y - \hat{Y} ( {ϕ}^{ℓ} , {ψ}^{*} ( {ϕ}^{ℓ} ) ) \} \qquad ( 20 )$$

$$Λ ( ϕ ) = [ \begin{matrix}\frac{\partial \hat{y} ( \text{?} , ϕ , {ψ}^{*} ( ϕ ) )}{\partial {ϕ}_{1}} & … & \frac{\partial \hat{y} ( \text{?} , ϕ , {ψ}^{*} ( ϕ ) )}{\partial {ϕ}_{{n}_{ϕ}}} \\ ⋮ & … & ⋮ \\ \frac{\partial \hat{y} ( {t}_{N} , ϕ , {ψ}^{*} ( ϕ ) )}{\partial {ϕ}_{1}} & … & \frac{\partial \hat{y} ( {t}_{N} , ϕ , {ψ}^{*} ( ϕ ) )}{\partial {ϕ}_{{n}_{ϕ}}}\end{matrix} ] \qquad ( 21 )$$

$$\text{?} \text{indicates text missing or illegible when filed}$$

When it is difficult to directly obtain the sensitivity function, an approximate value of the sensitivity function is used instead of the sensitivity function. That is, a gradient approximate value is used instead of the gradient itself. Also in this case, for example, the calculation formula in the case of using the one-sided difference is Equation (22).

$$\frac{\partial \hat{y} ( \text{?} , ϕ , {ψ}^{*} ( ϕ ) )}{\partial {ϕ}_{j}} \approx \frac{\hat{y} ( \text{?} , ϕ + {Δ}_{j} {e}_{j} , {ψ}^{*} ( ϕ + {Δ}_{j} {e}_{j} ) ) - \hat{y} ( \text{?} , ϕ , {ψ}^{*} ( ϕ ) )}{{Δ}_{j}} \qquad ( 22 )$$

$$\text{?} \text{indicates text missing or illegible when filed}$$

### <Nelder-Mead Method>

As an example, when the Nelder-Mead method is used, evaluation function values L(ϕ^{1,1}), L(ϕ^{1,2}), . . . , L(ϕ^{1,nϕ+1}) are calculated using n_{ϕ}+1 variables ϕ^{1,1}, ϕ^{1,2}, . . . , ϕ^{1,nϕ+1} with respect to the number of iterations 1 and the number of nonlinear parameters n_{ϕ} within one parameter update. Further, evaluation function values are also calculated for parameter values subjected to four types of operations of mirroring, expansion, contraction, and reduction. Then, the parameter is updated from ϕ¹ to ϕ¹⁺¹ according to a known algorithm while using the evaluation function values calculated in this manner.

As described above, depending on the nonlinear optimization method, it is necessary to obtain the evaluation functions or the output estimation values for a plurality of different nonlinear parameter estimation values in order to update the nonlinear parameter estimation values.

Note that, although description has been omitted because of deviation from the gist of the present application, even in a case where the original problem P1 includes at least one of the equality constraint and the inequality constraint on the nonlinear parameters ϕ, a known constrained nonlinear optimization method can be applied in updating of the nonlinear parameters ϕ. For example, a local solution can be obtained by the application of the interior point method, the sequential quadratic programming method, or the like described above.

The above is the details of the parameter estimation technique of the present application described with a general problem as a target. On the premise of the above details, a case where the present technology is applied to the storage battery 1 will be described.

### <Application to Storage Battery>

As described with reference to FIG. 1, the current detection device 21 detects the current of the storage battery 1 and outputs a detected current value I. The voltage detection device 22 detects a terminal voltage of the storage battery 1 and outputs a detected voltage value V. Note that, when the storage battery 1 is configured by series-parallel connection of a plurality of cells, the detection current and the detection voltage may be those of a single cell or the plurality of cells that are a part constituting the storage battery 1. In the following description, it is assumed that the sampling period of the time-series data is tₛ seconds. Note that the sampling period t_{b} does not need to be fixed, and may be variable.

The time-series data acquisition unit 31 acquires time-series data {I(tₖ)|k=0, 1, . . . , N} of the detected currents and time-series data {V(tₖ)|k=0, 1, . . . , N} of the detected voltages for a time series {tₖ|k=0, 1, . . . , N} of certain times. When a case where the sampling period tₛ is fixed is considered for simplification, a relationship of tₖ=t₀+ktₛ is established with respect to the initial time to. Note that the time-series data may be held inside the time-series data acquisition unit 31, or may be acquired via an external PC, a server, a cloud, or the like.

The model acquisition unit 32 holds a storage battery model for the storage battery 1 to be estimated, and the storage battery model is used in the parameter estimation unit 33. Then, parameters of the storage battery model including initial values are appropriately updated on the basis of the parameters estimated by the parameter estimation unit 33. Note that the storage battery model held by the model acquisition unit 32 may be originally held inside the model parameter estimation device 3, or may be acquired from an external PC, a server, a cloud, or the like.

As the storage battery model, for example, an equivalent circuit model as shown in FIG. 3 is used. In FIG. 3, a resistor R₀ is for representing a DC component of an over-voltage deriving from an electrolytic solution resistance, a collector metal resistance, a contact resistance, a charge transfer resistance, and the like of the storage battery 1. In addition, a resistance element R_{d} and a capacitor element C_{d} is for representing a relaxation component of an overvoltage deriving from a diffusion component of the storage battery 1.

At this time, a state space model of the storage battery 1 is described as, for example, Equation (23) to Equation (25).

$$\dot{q} = I - {I}_{off} \qquad ( 23 )$$

$${\dot{q}}_{d} = \frac{1}{\text{?}} {q}_{d} + I - {I}_{off} \qquad ( 24 )$$

$$V = \text{?} ( I - {I}_{off} ) + \frac{{q}_{d}}{{C}_{d}} + \text{?} ( q ) \qquad ( 25 )$$

$$\text{?} \text{indicates text missing or illegible when filed}$$

Here, q is electric quantity, I is a detected current value (detected current), I_{off} is a current offset error included in the detected current, q_{d} is a charge stored in the capacitor element C_{d}, and f_{OCV} is a function (OCV function f_{OCV}) representing an OCV characteristic depending on the electric quantity q of the storage battery 1. Note that the electric quantity q may be a normalized value, and in this case, the CV function f_{OCV} is also a function for the normalized electric quantity q.

When a discrete-time state space model is used, for example, Equation (23) to Equation (25) are converted into Equation (26) to Equation (28) by the zero-order hold.

$${q}_{k + 1} = {q}_{k} + {I}_{k} - {I}_{off} \qquad ( 26 )$$

$${q}_{d , k + 1} = \text{?} {q}_{d , k} + {τ}_{d} ( 1 - \text{?} ) ( {I}_{k} - {I}_{off} ) \qquad ( 27 )$$

$${V}_{k} = \text{?} ( {I}_{k} - {I}_{off} ) + \frac{{q}_{d , k}}{{C}_{d}} + \text{?} ( {q}_{k} ) \qquad ( 28 )$$

$$\text{?} \text{indicates text missing or illegible when filed}$$

As another storage battery model, a Foster-type equivalent circuit model in which multiple CR parallel elements are connected in series as shown in FIG. 4 may be used. The equivalent circuit model shown in FIG. 4 is a more detailed storage battery model than the equivalent circuit model shown in FIG. 3 because the three CR parallel elements are connected in series. Of course, the number of CR parallel elements connected in series may be any number.

In addition, when a diffusion impedance is approximated by the Foster type circuit, each CR parallel element can be expressed as follows using only a diffusion resistance R_{d} and a diffusion capacitance C_{d} (for example, refer to Kuhn, Estelle, et al. “Modelling Ni-mH battery using Cauer and Foster structures.” Journal of power sources 158.2 (2006): 1490-1497.).

$${R}_{i} = \frac{8 {R}_{d}}{{( 2 i - 1 )}^{2} {π}^{2}} , {C}_{i} = \frac{{C}_{d}}{2} for i = 1 , 2 , … , {n}_{d} \qquad ( 29 )$$

Here, n_{d} is an approximation order. For example, when the approximation order n_{d}=3, the diffusion impedance is approximated by three stages of the CR parallel element as in the equivalent circuit model of FIG. 4.

At this time, Equation (27) and Equation (28) become Equation (30) and Equation (31).

$$\text{?} = \frac{1}{{k}_{i} {τ}_{d}} \text{?} + I - {I}_{off} for i = 1 , 2 , … , {n}_{d} \qquad ( 30 )$$

$$\text{?} = \text{?} ( I - {I}_{off} ) + \frac{2}{{C}_{d}} \text{?} + \text{?} ( q ) \qquad ( 31 )$$

$$\text{?} \text{indicates text missing or illegible when filed}$$

Here, kᵢ is as described in Equation (32)

$${k}_{i} = 4 / ( {( 2 i - 1 )}^{2} {π}^{2} ) \qquad ( 32 )$$

Note that other battery models may be used, for example, a Cauer type circuit may be used. Alternatively, a so-called electrochemical model that attempts to directly describe an internal phenomenon of the storage battery 1 without using an equivalent circuit may be used. As the model of the storage battery 1, various known models can be used, and the model is not limited as long as the model can be expressed in the framework of Equation (1) or Equation (3). Note that, for the sake of simplicity, the equivalent circuit model described with reference to FIG. 3 is assumed in the following description.

As the OCV function f_{OCV} representing the OCV characteristic, typically, a linear or piece-wise linear function with respect to the electric quantity q is used. For example, when a polynomial is used, it is expressed as in Equation (33), and a parameter linear expression is possible.

$$\text{?} ( q ) = \text{?} = [ \text{?} , \text{?} , … \text{?} ] [ \begin{matrix}\text{?} \\ \text{?} \\ ⋮ \\ \text{?}\end{matrix} ] \qquad ( 33 )$$

$$\text{?} \text{indicates text missing or illegible when filed}$$

Here, np represents the degree of the polynomial and cᵢ is a coefficient of qᵢ.

Alternatively, the piece-wise linear function (first order spline curve) shown in Equation (34) is used.

$$\text{?} ( q ) = \{ \begin{matrix}\text{?} + {b}_{1} & for {p}_{1} \leq q \leq {p}_{2} \\ ⋮ & ⋮ \\ \text{?} + \text{?} & for \text{?} \leq q \leq \text{?}\end{matrix} \qquad ( 34 )$$

$$\text{?} \text{indicates text missing or illegible when filed}$$

Here, mₛ (≥2) is the number of nodes, and in Equation (34), the function is divided into mₛ−1 sections by n, points of q=p₁, p₂, . . . , pₘₛ, and when mₛ≥3, Equation (35) is satisfied as the equality constraint.

$${a}_{i} {p}_{i + 1} + {b}_{i} = {a}_{i + 1} {p}_{i + 1} + {b}_{i + 1} for i = 1 , … , {m}_{s} - 2 \qquad ( 35 )$$

Alternatively, a cubic spline curve of Equation (36) is used.

$$\text{?} ( q ) = \{ \begin{matrix}\text{?} {q}^{3} + {b}_{1} {q}^{2} + {c}_{1} q + {d}_{1} & for {p}_{1} \leq q \leq {p}_{2} \\ ⋮ & ⋮ \\ \text{?} {q}^{3} + \text{?} {q}^{2} + \text{?} q + \text{?} & for \text{?} \leq q \leq \text{?}\end{matrix} \qquad ( 36 )$$

$$\text{?} \text{indicates text missing or illegible when filed}$$

Note that, when mₛ≥3, Equation (37) is satisfied as the equality constraint.

$${a}_{i} {p}_{i + 1}^{3} + {b}_{i} {p}_{i + 1}^{2} + {c}_{i} {p}_{i + 1} + {d}_{i} = \text{?} + \text{?} + \text{?} + \text{?} \qquad ( 37 )$$

$$3 {a}_{i} {p}_{i + 1}^{2} + \text{?} {p}_{i + 1} + {c}_{i} = 3 \text{?} + \text{?} + \text{?}$$

$$6 \text{?} + 2 {b}_{i} = 6 {a}_{i + 1} {p}_{i + 1} + 2 {b}_{i + 1}$$

$$for i = 1 , … , \text{?} - 2$$

$$\text{?} \text{indicates text missing or illegible when filed}$$

Alternatively, a spline curve of any other order is used.

A parameter linear expression is also possible in a piece-wise polynomial such as a spline curve. As an example, in the case of a piece-wise linear function, it can be expressed as in Equation (38). Here, δ_{i, k} is as shown in Equation (39).

$$\text{?} ( q ( \text{?} ) ) = [ \text{?} q ( \text{?} ) , … \text{?} q ( \text{?} ) , \text{?} , … , \text{?} ] [ \begin{matrix}\text{?} \\ ⋮ \\ \text{?} \\ \text{?} \\ ⋮ \\ \text{?}\end{matrix} ] \qquad ( 38 )$$

$$\text{?} = \{ \begin{matrix}1 , & if {p}_{i} \leq q ( \text{?} ) \leq {p}_{i + 1} \\ 0 , & otherwise\end{matrix} \qquad ( 39 )$$

$$\text{?} \text{indicates text missing or illegible when filed}$$

Similarly, a parameter linear expression is possible in other cases, such as a cubic spline curve. Further, as another OCV function f_{OCV}, it is also possible to consider a case including both the linear parameters V and the nonlinear parameters ϕ. In this case, the function form is as shown in Equation (40).

$$\text{?} ( x ) = \text{?} ( q , \text{?} ) \text{?} \qquad ( 40 )$$

$$\text{?} \text{indicates text missing or illegible when filed}$$

Here, g_{OCV} is a vector-valued function, and ϕ_{OCV} and ψ_{OCV} are vectors of the nonlinear parameters ϕ and the linear parameters ψ included in the OCV function f_{OCV}, respectively.

As another OCV function f_{OCV}, it is also possible to consider the case of including only the nonlinear parameters ϕ. That is, the function form of the OCV function f_{OCV} is not necessarily limited to the form including the linear parameters ψ. However, when a large number of linear parameters ψ are included, in particular, the advantage of the approach of converting the problem P1 into the problem P2 in the present application is strongly exploited. Note that, in the following, a case where Equation (34) is used as the OCV function f_{OCV} will be described.

The nonlinear parameter update unit 331 updates the nonlinear parameters ϕ of the storage battery model on the basis of the time-series data {I(tₖ)|k=0, 1, . . . , N} of the detected currents, the time-series data {V(tₖ)|k=0, 1, . . . , N} of the detected voltages, and the storage battery model. Note that, here, the nonlinear parameters 4 are as shown in Equation (41).

$$ϕ = [ \begin{matrix}{τ}_{d} & {I}_{off} & \text{?}\end{matrix} \qquad ( 41 )$$

$$\text{?} \text{indicates text missing or illegible when filed}$$

That is, in the state space model of the storage battery 1, this refers to parameters included in the state equation and nonlinear parameters (parameters that cannot be expressed as parameter linear expression) included in the output equation. Note that it is not necessary to include all the nonlinear parameters ϕ in the estimation parameters, for example, in the case where a specific nonlinear parameter value is known.

Depending on how the state space model of the storage battery 1 is created, the elements of the nonlinear parameters ϕ may vary. For example, when the nonlinear parameters ϕ_{OCV} are not included in the OCV function f_{OCV}, the nonlinear parameters ϕ also do not necessarily include ϕ_{OCV}. Further, the parameters included in the state equation of Equation (24) and Equation (30) are only a time constant Ca and the current offset error I_{off}, but other parameters may also be included in the state equation depending on the modeling method.

For example, the time constant in a case where multi-stages of the CR parallel element are expressed by approximation of the diffusion impedance as in Equation (29) is one parameter of only Td, but in a case where the multi-stages of the CR parallel element are not expressed by the approximation, the parameters of the time constants independently exist by the number of the CR parallel elements. In addition, for example, in a case where the state equation of a CR overvoltage of Equation (42) is used instead of the state equation of a CR overvoltage of Equation (24) and the output equation is set to Equation (43) instead of Equation (25), C_{d} is included in the nonlinear parameters ϕ, not in the linear parameters ψ.

$$\text{?} = \frac{1}{{τ}_{d}} {V}_{d} + \frac{1}{{C}_{d}} ( I - {I}_{off} ) \qquad ( 42 )$$

$$V = {R}_{0} ( I - {I}_{off} ) + {V}_{d} + {f}_{OCV} ( q ) \qquad ( 43 )$$

$$\text{?} \text{indicates text missing or illegible when filed}$$

However, in this case, considering that both τ_{d} and C_{d} are included in the nonlinear parameters ϕ, it is better to use Equation (24) in order to make the most of the advantage of the technical idea of the present application.

As a specific method of updating the nonlinear parameters ϕ, it is possible to use a nonlinear optimization method based on a known iterative calculation as described above.

Predetermined values are used as the initial values of the nonlinear parameters ϕ. The predetermined values use a prior knowledge of true values of the nonlinear parameters ϕ, if possible. For example, since it is known that the diffusion time constant τ_{d} is usually about several tens of seconds to several hundreds of seconds in a lithium-ion storage battery, the diffusion time constant τ_{d} is set to, for example, 100 seconds as an initial value. Further, since the current offset error I_{off} is a very small value, an initial value is set to, for example, 0 A.

These settings are highly appropriate values for a typical lithium-ion storage battery and a current sensor, and do not depend on a series-parallel connection configuration of the storage battery 1. Therefore, there is an advantage in terms of the application to the product in that an initial value tuning operation is not necessary in many cases. In addition, when a characteristic evaluation result of the storage battery 1 of a brand-new product, data on a specification sheet, or the like can be available, these may be used. Further, in a case where parameter estimation has been performed in the past, the past estimation result may be used.

Note that the initial values may be set in the model acquisition unit 32, may be set in the nonlinear parameter update unit 331, or may be set in an initial value setting unit (not shown) separately provided. At this time, the initial values may be automatically set on the basis of the above-described prior knowledge, or may be set on the basis of an input by prompting the input after presenting prior information, initial value candidates, and the like by an input I/F (not shown).

Note that for the update of the nonlinear parameters ϕ, operations of the state quantity calculation unit 332 and the linear parameter estimation unit 333, which will be described later, may be included in the inside. For example, when gradient information of the evaluation function with respect to the nonlinear parameters ϕ is used to update the nonlinear parameters ϕ, the same calculations are required as in the state quantity calculation unit 332 and the linear parameter estimation unit 333.

The state quantity calculation unit 332 calculates time series values of the state quantities in the storage battery model (that is, state space model of storage battery 1) on the basis of the time-series data {I(tₖ)|k=0, 1, . . . , N} of the detected currents and the storage battery model. For example, the state quantities in the state space model of Equation (23) to Equation (25) refer to the electric quantity q and the electric charge q.

For the calculation of the time-series values of the state quantities based on the state space model, as described above, either a continuous-time or a discrete-time state space model may be used. In the former case, a known numerical solution method such as a fourth-order Runge-Kutta method may be used, and in the latter case, calculation may be sequentially performed according to the model. Alternatively, it may be calculated on the basis of the solution of the state equation.

The linear parameter estimation unit 333 estimates the linear parameters ψ on the basis of the time-series data {I(tₖ)|k=0, 1, . . . , N} of the detected currents, the time-series data {V(tₖ)|k=0, 1, . . . , N} of the detected voltages, the storage battery model, and the state quantities, and calculates a model output of the voltage. Specifically, the linear parameters ψ can be expressed separately in the output equation as in Equation (44), thereby being expressed as in Equation (45).

$$V = {R}_{0} ( I - {I}_{off} ) + \frac{{q}_{d}}{{C}_{d}} + \text{?} ( q , \text{?} ) \text{?} = [ \begin{matrix}I - {I}_{off} , & {q}_{d} , & \text{?}\end{matrix} ( \text{?} ) [ \begin{matrix}{R}_{0} \\ \text{?} \\ \text{?}\end{matrix} ] \qquad ( 44 )$$

$$[ \begin{matrix}V ( {t}_{0} ) \\ ⋮ \\ V ( {t}_{N} )\end{matrix} ] = [ \begin{matrix}\text{?} ( \text{?} ) - {I}_{off} & {q}_{d} ( \text{?} ) & \text{?} ( q ( \text{?} ) , \text{?} ) \\ ⋮ & ⋮ & ⋮ \\ \text{?} ( {t}_{N} ) - {I}_{off} & {q}_{d} ( {t}_{N} ) & \text{?} ( q ( \text{?} ) , \text{?} )\end{matrix} ] [ \begin{matrix}\text{?} \\ \text{?} \\ \text{?}\end{matrix} ] ↔ \text{?} = G ( ϕ ) ψ \qquad ( 45 )$$

$$\text{?} \text{indicates text missing or illegible when filed}$$

Thus, the linear least squares solution of the linear parameters ψ with respect to estimated values of some nonlinear parameters ϕ can be estimated as Equation (46).

$$ψ ( ϕ ) = {( {G}^{T} ( ϕ ) G ( ϕ ) )}^{- 1} {G}^{T} ( ϕ ) v \qquad ( 46 )$$

Accordingly, the problem P1, which is a voltage error minimization problem based on the output error method in the storage battery 1, can be converted into the problem P2 by Equation (46). Further, the model output of the voltage can also be calculated by using the estimated values of the linear parameters 41.

If an equality constraint is included, the problem P3 may be considered in light of the equality constraint. For example, when the OCV function f_{OCV} is a linear spline curve (piece-wise linear function), the equation (35) needs to be satisfied, and therefore, when ψ_{OCV,i}=[aᵢ bᵢ]^{T}, the equality constraint equation becomes Equation (48) with respect to Equation (47).

$${χ}_{i} = {[ {p}_{i + 1} 1 ]}^{T} \qquad ( 47 )$$

$$[ \begin{matrix}0 & 0 & - \text{?} & \text{?} & & \\ ⋮ & ⋮ & & ⋱ & ⋱ & \\ 0 & 0 & & & \text{?} & \text{?}\end{matrix} ] [ \begin{matrix}\text{?} \\ {C}_{d}^{- 1} \\ \text{?} \\ \text{?} \\ ⋮ \\ \text{?}\end{matrix} ] = [ \begin{matrix}0 \\ 0 \\ 0 \\ 0 \\ ⋮ \\ 0\end{matrix} ] \qquad ( 48 )$$

$$\text{?} \text{indicates text missing or illegible when filed}$$

In addition, in a case where the OCV function f_{OCV} is a cubic spline curve, since Equation (37) needs to be satisfied, when ψ_{OCV,i}=[aᵢ bᵢ cᵢ dᵢ], the equality constraint equation becomes Equation (50) with respect to Equation (49).

$$\text{?} = [ \begin{matrix}\text{?} & \text{?} & \text{?} & 1\end{matrix} \text{?} \qquad ( 49 )$$

$$\text{?} = [ \begin{matrix}\text{?} & \text{?} & 1 & 0\end{matrix} \text{?}$$

$$\text{?} = [ \begin{matrix}6 \text{?} & 2 & 0 & 0 \text{?}\end{matrix}$$

$$[ \begin{matrix}0 & 0 & - \text{?} & \text{?} & & & \\ 0 & 0 & - \text{?} & \text{?} & ⋱ & & \\ 0 & 0 & - \text{?} & \text{?} & ⋱ & ⋱ & \\ ⋮ & ⋮ & & ⋱ & ⋱ & ⋱ & \\ 0 & 0 & & ⋱ & ⋱ & - \text{?} & \text{?} \\ 0 & 0 & & & ⋱ & - \text{?} & \text{?} \\ 0 & 0 & & & & - \text{?} & \text{?}\end{matrix} ] [ \begin{matrix}\text{?} \\ {C}_{d}^{- 1} \\ \text{?} \\ \text{?} \\ ⋮ \\ \text{?}\end{matrix} ] = [ \begin{matrix}0 \\ 0 \\ 0 \\ 0 \\ ⋮ \\ 0\end{matrix} ] \qquad ( 50 )$$

$$\text{?} \text{indicates text missing or illegible when filed}$$

By formulating in this way, the problem to be solved can be treated as the problem P3 and the sub-problem SP3. The solution method at this time is as described above. Note that the equality constraint equation is not limited to those described in the above example, and may be a single or multiple arbitrary equations expressed by a linear equality constraint equation.

Further, it is also possible to consider the case of including the inequality constraint on the linear parameters ψ. For example, in a case where it is desired to reflect prior knowledge regarding upper and lower limit constraints of R_{0,min}≤R₀≤R_{0,max} and C_{d,min}≤C_{d}≤C_{d,max} with respect to R₀ and C_{d}, the inequality constraint may be expressed as in Equation (51).

$$[ \begin{matrix}- 1 & 0 & 0 & … & 0 \\ 1 & 0 & 0 & … & 0 \\ 0 & 1 & 0 & … & 0 \\ 0 & - 1 & 0 & … & 0\end{matrix} ] [ \begin{matrix}\text{?} \\ {C}_{d}^{- 1} \\ \text{?}\end{matrix} ] \leq [ \begin{matrix}- \text{?} \\ \text{?} \\ \text{?} \\ - \text{?}\end{matrix} ] \qquad ( 51 )$$

$$\text{?} \text{indicates text missing or illegible when filed}$$

This allows the problem to be solved to be treated as the problem P4 and the sub-problem SP4. The solution method at this time is as described above. Note that the inequality constraint is not limited to the example described above, and may be a single or multiple arbitrary inequalities expressed by a linear inequality constraint.

Although a polynomial approximation method and a spline approximation method of the OCV function f_{OCV} have been described here, the dependency of the circuit parameters such as R₀, R_{d}, C_{d}, and τ_{d} on the electric quantity may be modeled by the similar method. Further, the temperature dependency of the circuit parameters may be modeled by the similar method. Note that, in the case of modeling the temperature dependence, it is necessary to separately measure the temperature of the storage battery 1, and in that case, the model parameter estimation device 3 needs to acquire an output of a temperature detector. As the temperature model, a well-known Arrhenius equation or the like can be used.

The determination unit 334 determines convergence of the parameter estimation values and the voltage estimation values on the basis of the time-series data {V(tₖ)|k=0, 1, . . . , N} of the detected voltages, the model output of the voltage, the linear parameter estimation values, and the nonlinear parameter estimation values. If a predetermined determination criterion is satisfied, the estimation is terminated, and the model parameters are output to the outside. If the determination criterion is not satisfied, the process returns to the nonlinear parameter update unit 331, and the update of the nonlinear parameters ϕ is repeated.

Specifically, when the j-th element of the 1-th estimated value of the parameter θ is θⱼ¹, it is determined whether or not Equation (52) is satisfied as in Patent Document 1.

$$\text{?} \vert \frac{{θ}_{j}^{ℓ + 1} - {θ}_{j}^{ℓ}}{{θ}_{j}^{ℓ}} \vert < \text{?} \qquad ( 52 )$$

$$\text{?} \text{indicates text missing or illegible when filed}$$

where, n_{θ} is the number of elements of θ, and ε^{θ} is a predetermined sufficiently small value.

Alternatively, it is determined whether or not Equation (53) is satisfied only for the nonlinear parameters ϕ.

$$\text{?} \vert \frac{{ϕ}_{j}^{ℓ + 1} - {ϕ}_{j}^{ℓ}}{{ϕ}_{j}^{ℓ}} \vert < \text{?} \qquad ( 53 )$$

$$\text{?} \text{indicates text missing or illegible when filed}$$

where, n_{ϕ} is the number of elements of ϕ, and ε^{ϕ} is a predetermined sufficiently small value.

Alternatively, based on the root-mean-square error (RMSE) with respect to the voltage, it is determined whether or not Equation (54) is satisfied.

$$RMSE ( \text{?} ) = \sqrt{\frac{1}{N + 1} ‖ \text{?} - G ( \text{?} ) \text{?}} < \text{?} \qquad ( 54 )$$

$$\text{?} \text{indicates text missing or illegible when filed}$$

Here, ε_{V} is a predetermined sufficiently small value.

Alternatively, the determination may be made on the basis of a mean absolute error (MAE) with respect to the voltage, or it is determined whether or not the number of repetitions of the estimation of the nonlinear parameters ϕ has reached a predetermined upper limit value as a convergence condition. Alternatively, a composite determination is performed by the multiple methods described above, or another arbitrary convergence determination method may be used. Since various methods are known as a convergence determination method of the estimation parameters in the nonlinear optimization, the convergence determination method is not limited.

Note that the final parameter estimation values of the parameter estimation unit 33 may be stored in the model acquisition unit 32 and used as the initial values of the next model parameter estimation, or may be stored in an external PC, a server, a cloud, or the like.

### <Processing Procedure of Model Parameter Estimation Device>

Next, a processing procedure of the model parameter estimation device 3 according to Embodiment 1, that is, the model parameter estimation method will be described with reference to a flowchart of FIG. 5. Note that, here, the most typical case, that is, the case of using the nonlinear optimization method using a gradient approximation value will be described.

First, the time-series data acquisition unit 31 acquires the current values I of the storage battery 1 output by the current detection device 21 and the voltage values V of the storage battery 1 output by the voltage detection device 22 as time-series values of measured values (step S1310).

Next, the model acquisition unit 32 acquires a storage battery model held externally or internally, and sets or reads initial values of the nonlinear parameters ϕ (step S1320). As the storage battery model, for example, the state space model represented by Equation (23) to Equation (25) or Equation (26) to Equation (28) that correspond to Equation (3) is acquired.

The acquired time-series data, the storage battery model, and the initial values are output to the parameter estimation unit 33, and the following repetitive calculation (step S2331 to step S2400) is executed in each unit in the parameter estimation unit 33.

In step S2331, the nonlinear parameter update unit 331 updates the nonlinear parameters ϕ according to a nonlinear optimization method, such as a type of gradient method based on iterative calculations, such that errors minimized for the linear parameters ψ are reduced. In the calculation of the gradient, for example, when a gradient approximate value by the one-sided difference is used, the gradient approximate value is calculated on the basis of an output estimation value with respect to a perturbation value for each element of a previous nonlinear parameter update value (previous value) to be described later. Note that, in the calculation of the gradient approximate value by the one-sided difference or the like, the output estimation value for the previous value is also used. Note that, at the first time, predetermined values are set as the initial values of the nonlinear parameters (for example, τ_{d}=100, I_{off}=0, or the like).

In step S2332, the state quantity calculation unit 332 calculates the state quantities of the storage battery model on the basis of the state equation of the storage battery model by the updated nonlinear parameters ϕ. In step S2333, the linear parameter estimation unit 333 estimates the linear parameters ψ and output values of the storage battery model on the basis of the state quantities outputted from the state quantity calculation unit 332.

Then, in step S2334, the determination unit 334 determines convergence of the parameter estimation in the parameter estimation unit 33 according to a predetermined convergence determination condition. When it is determined that the convergence determination condition is satisfied (“Yes” in step S2400), the parameter estimation is ended, and the parameters of the estimation result is output to the outside. At this time, the parameters of the estimation result may be held by the model acquisition unit 32.

On the other hand, in a case where it is determined that the convergence determination condition is not satisfied (“No” in step S2400), the process proceeds to step S3331, and the execution of each step after step S3331 is continued.

In step S3331, the nonlinear parameter update unit 331 sets a perturbation value for each of the elements of the nonlinear parameters. In step S3332, the state quantity calculation unit 332 calculates the state quantities of the storage battery model with respect to each of the perturbation values for each of the elements of the nonlinear parameters on the basis of the state equation of the storage battery model according to each of the perturbation values for each of the elements of the nonlinear parameters set by the nonlinear parameter update unit 331.

In step S3333, the linear parameter estimation unit 333 estimates the linear parameters ψ with respect to each of the perturbation values for each of the elements of the nonlinear parameters and the output value of the storage battery model on the basis of the state quantities with respect to each of the perturbation values for each of the elements of the nonlinear parameters outputted from the state quantity calculation unit 332. Then, the execution of each step after the above-described step S2331 is continued.

The above is the processing procedure of the model parameter estimation device 3 according to Embodiment 1, that is, an example of the operation in the model parameter estimation method. The details and the order of the processing described with reference to FIG. 5 are merely an example, and the details and the order are not limited thereto.

Next, a result of applying the model parameter estimation device 3 or the model parameter estimation method according to Embodiment 1 to time-series data of currents and voltages during operation of a certain storage battery system 100 will be described with reference to FIG. 6. In this application, the current and voltage in the storage battery system 100 with series-parallel connection configuration are converted to a cell as a storage battery 1.

Here, the model of the storage battery 1 is approximated by the Foster-type circuit shown in FIG. 4, and R₁, R₂, R₃, C₁, C₂, and C₃ are in accordance with Equation (29) for finite approximation of the diffusion impedance. Further, as the OCV function f_{OCV}, a cubic spline curve divided by equal intervals of mₛ=10 is used. For the sake of simplicity, the nonlinear parameters ϕ are assumed to be only τ_{d}, and the linear parameters ψ are assumed to be R₀, C_{d}, and all parameters of the third order spline curve.

In the time-series data of the current value I in the upper part of FIG. 6, the first half is free charging and discharging, and the second half is constant power charging. In any case, it can be seen that the actual data (measured values: solid line) in the middle row and the model output (estimated values: broken line) in the lower row accurately coincide with each other.

In addition, the OCV function f_{OCV} estimated at this time is shown in FIG. 7. Note that the horizontal axis represents the electric quantity q/q_{typ} normalized by a certain standard capacity q_{typ}. In the estimation result, the nonlinear variation of the OCV with respect to the electric quantity of q/q_{typ}, which is not completely linear, can be modeled while each of the points are smoothly connected. Due to the effect above, regarding the voltages in FIG. 6 (middle row: actual data, lower row: model output), the voltages including a subtle uneven shape during charging can be accurately estimated.

### Embodiment 2

In Embodiment 1, the processing in the case where the OCV function is unknown has been described. In Embodiment. 2, a case where the OCV function is known will be described. Note that the configuration of the model parameter estimation device and the basic operation of the model parameter estimation method are the same as those in Embodiment 1, and thus the description of the same parts will be omitted and the drawings used in Embodiment 1 will be referred to.

In a case where the OCV function f_{OCV} is known, in the state space model of the storage battery 1 expressed by Equation (23) to Equation (25), Equation (25) can be expressed as Equation (55) using a full charge capacity qₘₐₓ.

$$V = {R}_{0} ( I - {I}_{off} ) + \frac{{q}_{d}}{{C}_{d}} + \text{?} ( \frac{q}{{q}_{max}} ) \qquad ( 55 )$$

$$\text{?} \text{indicates text missing or illegible when filed}$$

At this time, since the OCV function f_{OCV} is known, the nonlinear parameters ϕ are expressed by Equation (56).

$$ϕ = {[ {τ}_{d} {I}_{off} {q}_{max} ]}^{T} \qquad ( 56 )$$

Further, when the output equation is converted, it is as shown in Equation (57), and since the parameter linear expression is possible as in Embodiment 1, the linear parameters y are as shown in Equation (58).

$$V - \text{?} ( \frac{q}{{q}_{max}} ) = {R}_{0} ( I - {I}_{off} ) + \frac{{q}_{d}}{{C}_{d}} = [ \begin{matrix}I - {I}_{off} & {q}_{d} \text{?} [ \begin{matrix}{R}_{0} \\ {C}_{d}^{- 1}\end{matrix} ]\end{matrix} \qquad ( 57 )$$

$$ψ = [ \begin{matrix}{R}_{0} & {C}_{d}^{- 1} \text{?}\end{matrix} \qquad ( 58 )$$

$$\text{?} \text{indicates text missing or illegible when filed}$$

In this case, unlike Embodiment 1, there is an advantage that the full charge capacity qₘₐₓ can be included in the estimation.

Further, as more detailed information of the OCV function f_{OCV}, it is assumed that a positive-electrode potential function fₚ and a negative-electrode potential function fₙ are known, and the OCV function f_{OCV} can be expressed as Equation (59) using the electrode parameters.

$$\text{?} ( s ) = {f}_{p} ( \frac{q + \text{?}}{{q}_{p , max}} ) - {f}_{n} ( \frac{q + \text{?}}{{q}_{, max}} ) \qquad ( 59 )$$

$$\text{?} \text{indicates text missing or illegible when filed}$$

Here, among the electrode parameters, q_{p,0} and q_{n,0} are initial charge amounts of the positive electrode and the negative electrode, respectively, and q_{p,max} and q_{n,max} are full charge capacities of the positive electrode and the negative electrode, respectively. When it is expressed in this way, the nonlinear parameters ϕ are as shown in Equation (60).

$$ϕ = {[ {τ}_{d} {I}_{off} {q}_{p , 0} {q}_{p , max} {q}_{n , o} {q}_{n , max} ]}^{T} \qquad ( 60 )$$

The linear parameters ψ are the same as in Equation (58).

In this case, the OCV function f_{OCV} can be modeled in more detail, and the deterioration of the storage battery 1 can be diagnosed in more detail. Specifically, it is possible to distinguish and grasp a decrease in a positive-electrode capacity, a decrease in a negative-electrode capacity, and a deviation in the electric quantity between the positive electrode and the negative electrode due to deterioration of the storage battery 1. Note that the deviation in the electric quantity between the positive electrode and the negative electrode is said to be caused by a phenomenon that occurs mainly due to the growth of a film (SEI: Solid Electrolyte Interface) formed on the surface of the negative electrode and the precipitation of lithium, and this causes a decrease in the full charge capacity of the storage battery 1.

As described above, in the model parameter estimation device 3 or the model parameter estimation method of the present application, the update of the nonlinear parameters Q and the estimation of the linear parameters w are separated. Alternatively, the nonlinear parameters ϕ are updated in consideration of a problem in which the linear least squares solution of the linear parameters is embedded as in the problem P2. As described above, there are roughly three advantages in the optimization calculation.

First, there is a reduction in the initial value dependency due to the fact that the initial value setting only requires the nonlinear parameters 4. Second, there is a reduction in the amount of calculation. Third, numerical stability is improved.

In the estimation of the linear parameters ψ, it is possible to obtain an optimal solution in any of an unconstrained linear least squares problem, a linear equality constrained linear least squares problem, and a linear inequality constraint problem. In particular, in the unconstrained linear least squares problem, a linear least squares solution is obtained without iterative computation. Also, in the linear equality constrained linear least squares problem, a global optimal solution can be obtained by the method of Lagrange multiplier without repetitive calculation.

These advantages will be more pronounced when the battery model is more complex and the number of parameters to be estimated increases. Therefore, by separately holding the positive-electrode potential characteristic and the negative-electrode potential characteristic as the OCV characteristic to be held in advance and estimating a part or all of the electrode parameters, it is also useful in a case where more detailed modeling and deterioration diagnosis are performed.

Here, when the continuous-time system identification method based on the output error method described in Patent Document 1 is examined again, although the OCV characteristic data is not essential, a model parameter estimation method in a case where the OCV characteristic data is not held is not clearly described. In practice, a model parameter estimation technique that does not assume the OCV characteristic data is also important. For example, since it is known that the OCV characteristic varies due to deterioration or the like, it is important to estimate model parameters including the OCV characteristic in order to improve the accuracy of estimation and to apply the estimation to deterioration diagnosis.

Further, in the reuse of the storage battery, modeling may be required in a situation where there is no or little prior information on the true values of the model parameters including the OCV characteristic. In a case where the OCV characteristic is expressed by a certain function using parameters and is collectively estimated by including the parameters in the model parameters, the method described in Patent Document 1 has the above-described problems of the initial value setting and the convergence, and thus it is more difficult to converge the OCV characteristic to the optimal value.

In contrast, in the present application, the OCV characteristic, which is the relationship between the electric quantity (it may be the SOC or the normalized electric quantity) and the OCV, is expressed by a function including parameters, and then the parameters are estimated. This makes it possible to estimate the OCV characteristic even if the OCV characteristic is unknown.

In particular, when it is expressed by a function including a large number of linear parameters ψ such as a polynomial or a piece-wise polynomial, the feature of the present application in which the process of updating the nonlinear parameters ϕ and the process of estimating the linear parameters ψ are separated from each other is utilized. This makes it possible to easily estimate all the parameters without finely setting the initial values of the large number of linear parameters ψ. In addition, as described above, in the estimation of the linear parameters ψ, since a global solution is obtained even when the linear equality constraint is included, it is possible to easily perform the parameter estimation even in a case where the OCV function f_{OCV} is treated as a piece-wise polynomial including the linear equality constraint. Note that the use of a piece-wise polynomial rather than a polynomial makes it easier to accurately express a curve including local variations.

Although various exemplary embodiments and examples are described in the present application, various features, aspects, and functions described in one or more embodiments are not inherent in an application of the contents disclosed in a particular embodiment, and can be applicable alone or in their various combinations to each embodiment. Accordingly, countless variations that are not illustrated are envisaged within the scope of the art disclosed in the specification of the present application. For example, the case where at least one component is modified, added or omitted, and the case where at least one component is extracted and combined with a component disclosed in another embodiment are included.

As described above, the model parameter estimation device 3 according to the present application includes the state quantity calculation unit 332 to calculate the state quantities indicating the state of the storage battery 1 (for example, electric quantity q, electric charge q_{d}) with respect to the measured value of the current I on the basis of the state equation obtained by assigning values (for example, initial values) to nonlinear parameters ϕ for the state space model that represents the storage battery 1 using the nonlinear parameters ϕ and the linear parameters ψ, and the time-series data of each of the measured values of the current (current value I) and the terminal voltage (voltage value V) of the storage battery 1, the linear parameter estimation unit 333 to estimate the linear parameters T that minimize an error between the measured value of the voltage value V and the estimated value of the voltage V calculated on the basis of the state space model, the state quantities, and the measured value of the current I, the determination unit 334 to determine whether or not the estimated linear parameters ψ are converged, and the nonlinear parameter update unit 331 to repeatedly update the values of the nonlinear parameters ϕ so as to make the minimized error to be small until the predetermined convergence condition is satisfied and the determination unit 334 determines the convergence. Therefore, since the initial value setting is limited to only the nonlinear parameters ϕ, the parameters can be estimated with a small amount of information.

Further, the initial value dependency can be reduced, the amount of calculation is reduced, and the numerical stability is improved. In this case, it is possible to use, as the initial values, values that are generally known and have high validity for the storage battery and thus it is possible to perform the estimation without additional information even when the system is updated.

In particular, when the nonlinear parameter update unit 331 updates the values of the nonlinear parameters ϕ using a gradient or a gradient approximate value of the estimated value of the voltage V with respect to the nonlinear parameters ϕ, or using a gradient-free nonlinear optimization method, the convergence can be easily achieved.

Alternatively, when the nonlinear parameter update unit 331 generates, when updating the values of the nonlinear parameters ϕ, a perturbation value for each of the nonlinear parameters ϕ obtained by perturbing previous values that are values before the update, the state quantity calculation unit 332 calculates state quantities for each perturbation value, the linear parameter estimation unit 333 estimates the linear parameters v with respect to the state quantities for each perturbation value, and the nonlinear parameter update unit 331 calculates a gradient approximate value of the estimated value of the terminal voltage (voltage value V) with respect to the nonlinear parameters § on the basis of at least the estimated values of the linear parameters v with respect to the state quantities for each perturbation value, and updates the previous values on the basis of the calculated gradient approximate value, the convergence can be more reliably achieved.

In these cases, when the nonlinear parameters ϕ include at least one of the state of charge, the full charge capacity qₘₐₓ, and the diffusion time constant τ_{d} of the storage battery 1, and the offset current (current offset error I_{off}) of the sensor used to measure the current (current value I), and the linear parameters V include at least one of a DC resistance, the diffusion resistance R_{d}, and a capacitor capacity of the storage battery 1, the state of the storage battery 1 can be reliably evaluated.

In these cases, when the linear parameter estimation unit 333 estimates the linear parameters ψ using the linear least squares solution of the linear least squares problem, the amount of calculation is reduced.

In this case, when the state space model includes the OCV function f_{OCV} that represents a relationship between the electric quantity q and the open circuit voltage and that includes the linear parameters ψ, the storage battery 1 can be accurately modeled.

Further, when the OCV function f_{OCV} is a polynomial of the electric quantity q, and the linear parameters ψ include coefficients of the polynomial, the nonlinear variation of the OCV with respect to the electric quantity q can be modeled.

When the state space model includes the linear equality constraint on the linear parameters ψ, and the linear parameter estimation unit 333 estimates the linear parameters v by solving the linear least squares problem including the linear equality constraint by the method of Lagrange multiplier, the convergence can be made reliable by alternately repeating the update of the nonlinear parameters ϕ and the calculation of the linear parameters ψ by the method of Lagrange multiplier.

When the state space model includes the OCV function f_{OCV} of a piece-wise polynomial representing a relationship between the electric quantity q and the open circuit voltage and including the linear parameters ψ, the linear parameters ψ include linear parameters of the piece-wise polynomial, and the linear equality constraint includes a linear equality constraint at nodes of the piece-wise polynomial, the feature of the present application in which the process of updating the nonlinear parameters ϕ and the process of estimating the linear parameters ψ are separated from each other can be sufficiently utilized.

Alternatively, when the state space model includes the linear inequality constraint on the linear parameters ψ, and the linear parameter estimation unit 333 estimates the linear parameters ψ by solving the linear least squares problem including the linear inequality constraint, the optimal solution can be obtained.

In addition, when the state space model includes the OCV characteristic information representing a relationship between the state of charge and the open circuit voltage of the storage battery 1, and the nonlinear parameters ϕ include the full charge capacity qₘₐₓ, the degradation of the storage battery 1 can be diagnosed in detail.

In this case, when the state space model includes positive-electrode potential characteristic information representing a relationship between a positive-electrode electric quantity and a positive-electrode potential of the storage battery, and negative-electrode potential characteristic information representing a relationship between a negative-electrode electric quantity and a negative-electrode potential of the storage battery, and the nonlinear parameters ϕ include at least one of the positive-electrode capacity, the negative-electrode capacity, the positive-electrode electric quantity, and the negative-electrode electric quantity instead of the full charge capacity qₘₐₓ, the degradation of the storage battery 1 can be diagnosed in more detail.

Further, the model parameter estimation method of the present application includes the step (S1320) of setting initial values of the nonlinear parameters ϕ of the state space model that represents the storage battery 1 using the nonlinear parameters ϕ and linear parameters ψ, the state quantity calculation step (S2332) of calculating the state quantities indicating the state of the storage battery (for example, electric quantity q, electric charge q_{d}) with respect to a measured value of a current I on the basis of the state equation obtained by assigning values to the nonlinear parameters ϕ for the state space model, and time-series data of each of the measured values of the current (current value I) and the terminal voltage (voltage value V) of the storage battery 1, the linear parameter estimation step (S2333) of estimating the linear parameters g that minimize an error between the measured value of the terminal voltage V and an estimated value of the terminal voltage V calculated on the basis of the state space model, the state quantities, and the measured value of the current I, the determination step (S2334) of determining whether or not the estimated linear parameters N are converged, and the nonlinear parameter update step (S2331) of updating the nonlinear parameters by repeatedly updating the values of the nonlinear parameters ϕ so as to make the minimized error to be small until a predetermined convergence condition is satisfied and the linear parameters ψ are determined to be converged. Therefore, since the initial value setting is limited to only the nonlinear parameters ϕ, the parameters can be estimated with a small amount of information.

Further, the initial value dependency can be reduced, the amount of calculation is reduced, and the numerical stability is improved. In this case, it is possible to use, as the initial values, values that are generally known and have high validity for the storage battery, and thus it is possible to perform the estimation without additional information even when the system is updated.

In the nonlinear parameter update step (S2331), when values of the nonlinear parameters are updated by using a gradient or a gradient approximate value of the estimated value of the voltage V with respect to the nonlinear parameters ϕ, or by using a gradient-free nonlinear optimization method, the convergence can be easily achieved.

Alternatively, when the method is configured to further include a perturbation value setting step (S3331) of generating a perturbation value of each of the nonlinear parameters ϕ (their elements) obtained by perturbing previous values being values before the update when the values of the nonlinear parameters ϕ are updated, a per-perturbation state quantity calculation step (S3332) of calculating state quantities for each perturbation value, and a per-perturbation linear parameter estimation step (S3333) of estimating linear parameters ψ with respect to the state quantities for each perturbation value. In the nonlinear parameter update step (S2331), a gradient approximate value of the estimated value of the terminal voltage (voltage value V) with respect to the nonlinear parameters ϕ is calculated on the basis of at least the estimated values of the linear parameters with respect to the state quantities for each perturbation value, and the previous values are updated on the basis of the calculated gradient approximate value, the convergence can be more reliably achieved.

In these cases, when the nonlinear parameters ϕ include at least one of the state of charge, the full charge capacity qₘₐₓ, the diffusion time constant of the storage battery 1, and the offset current (current offset error I_{off}) of the sensor used to measure the current (current value I), and the linear parameters ψ include at least one of the DC resistance, the diffusion resistance R_{d}, and the capacitor capacity of the storage battery 1, the state of the storage battery 1 can be reliably evaluated.

In the linear parameter estimation step (S2333), when the linear parameters ψ are estimated using the linear least squares solution of the linear least squares problem, the amount of calculation is reduced.

In the case, when the state space model includes the OCV function f_{OCV} that represents a relationship between the electric quantity q and the open circuit voltage and that includes the linear parameters ψ, the storage battery 1 can be accurately modeled.

Further, when the OCV function f_{OCV} is a polynomial of the electric quantity q, and the linear parameters ψ include coefficients of the polynomial, the nonlinear variation of the OCV with respect to the electric quantity q can be modeled.

When the configuration is such that the state space model includes a linear equality constraint on the linear parameters ψ, and in the linear parameter estimation step (S2333), the linear parameters ψ are estimated by solving a linear least squares problem including the linear equality constraint by a method of Lagrange multiplier, the convergence can be made reliable by alternately repeating the update of the nonlinear parameters ϕ and the calculation of the linear parameters p by the method of Lagrange multiplier.

When the state space model includes the OCV function f_{OCV} of a piece-wise polynomial representing a relationship between the electric quantity q and the open circuit voltage and including the linear parameters ψ, the linear parameters ψ include linear parameters of the piece-wise polynomial, and the linear equality constraint includes a linear equality constraint at nodes of the piece-wise polynomial, the feature of the present application in which the process of updating the nonlinear parameters ϕ and the process of estimating the linear parameters ψ are separated from each other is sufficiently utilized.

Alternatively, when the state space model includes a linear inequality constraint on the linear parameters ψ, and in the linear parameter estimation step (S2333), the linear parameters ψ are estimated by solving a linear least squares problem including the linear inequality constraint, the optimal solution can be obtained.

Further, when the state space model includes OCV characteristic information representing a relationship between the state of charge and the open circuit voltage of the storage battery 1, and the nonlinear parameters ϕ include the full charge capacity qₘₐₓ, the degradation of the storage battery 1 can be diagnosed in detail.

At this time, when the configuration is such that the state space model includes positive-electrode potential characteristic information representing a relationship between a positive-electrode electric quantity and a positive-electrode potential of the storage battery 1, and negative-electrode potential characteristic information representing a relationship between a negative-electrode electric quantity and a negative-electrode potential of the storage battery 1, and the nonlinear parameters ϕ include at least one of a positive-electrode capacity, a negative-electrode capacity, the positive-electrode electric quantity, and the negative-electrode electric quantity instead of the full charge capacity qₘₐₓ, the degradation of the storage battery 1 can be diagnosed in more detail.

### DESCRIPTION OF REFERENCE NUMERALS AND SIGNS

1: storage battery, 21: current detection device, 22: voltage detection device, 3: model parameter estimation device, 31: time-series data acquisition unit, 32: model acquisition unit, 33: parameter estimation unit, 331: nonlinear parameter update unit, 332: state quantity calculation unit, 333: linear parameter estimation unit, 334: determination unit, I: current value, I_{off}: current offset error, q: electric quantity, qₘₐₓ: full charge capacity, R_{d}: diffusion resistance, V: voltage value, τ_{d}: diffusion time constant

1.-24. (canceled)

25. A model parameter estimation device comprising:
a state quantity calculator to calculate state quantities indicating a state of a target system with respect to a measured values of an input on a basis of a state equation obtained by assigning values to nonlinear parameters for a state space model that represents the target system using the nonlinear parameters and linear parameters, and time-series data of each of measured values of the input and an output of the target system;
a linear parameter estimator to estimate the linear parameters that minimize an error between the measured value of the output and an estimated value of the output calculated on a basis of the state space model, the state quantities, and the measured value of the input; and
a nonlinear parameter updater to repeatedly update the values of the nonlinear parameters so as to make the minimized error to be small until a predetermined convergence condition is satisfied.

26. The model parameter estimation device according to claim 25, wherein the state quantity calculator calculates the state quantities assuming that the target system is a storage battery, the input is a current of the storage battery, and the output is a terminal voltage of the storage battery.

27. The model parameter estimation device according to claim 25, wherein the nonlinear parameter updater updates the values of the nonlinear parameters using a gradient or a gradient approximate value of the estimated value of the terminal voltage with respect to the nonlinear parameters, or using a gradient-free nonlinear optimization method.

28. The model parameter estimation device according to claim 25, wherein
the nonlinear parameter updater generates, when updating the values of the nonlinear parameters, a perturbation value for each of the nonlinear parameters obtained by perturbing previous values that are values before the update;
the state quantity calculator calculates state quantities for each perturbation value;
the linear parameter estimator estimates the linear parameters with respect to the state quantities for each perturbation value; and
the nonlinear parameter updater calculates a gradient approximate value of the estimated value of the terminal voltage with respect to the nonlinear parameters on a basis of at least the estimated values of the linear parameters with respect to the state quantities for each perturbation value, and updates the previous values on a basis of the calculated gradient approximate value.

29. The model parameter estimation device according to claim 26, wherein the nonlinear parameters include at least one of a state of charge, a full charge capacity, and a diffusion time constant of the storage battery, and an offset current of a sensor used to measure the current, and the linear parameters include at least one of a DC resistance, a diffusion resistance, and a capacitor capacity of the storage battery.

30. The model parameter estimation device according to claim 26, wherein the linear parameter estimator estimates the linear parameters using a linear least squares solution of a linear least squares problem.

31. The model parameter estimation device according to claim 30, wherein the state space model includes an OCV function that represents a relationship between an electric quantity and an open circuit voltage and that includes the linear parameters.

32. The model parameter estimation device according to claim 31, wherein the OCV function is a polynomial of the electric quantity, and the linear parameters include coefficients of the polynomial.

33. The model parameter estimation device according to claim 26, wherein the state space model includes a linear equality constraint on the linear parameters, and the linear parameter estimator estimates the linear parameters by solving a linear least squares problem including the linear equality constraint by a method of Lagrange multiplier.

34. The model parameter estimation device according to claim 33, wherein the state space model includes an OCV function of a piece-wise polynomial representing a relationship between an electric quantity and an open circuit voltage and including the linear parameters, the linear parameters include linear parameters of the piece-wise polynomial, and the linear equality constraint includes a linear equality constraint at nodes of the piece-wise polynomial.

35. The model parameter estimation device according to claim 25, wherein the state space model includes a linear inequality constraint on the linear parameters, and the linear parameter estimator estimates the linear parameters by solving a linear least squares problem including the linear inequality constraint.

36. The model parameter estimation device according to claim 26, wherein the state space model includes OCV characteristic information representing a relationship between a state of charge and an open circuit voltage of the storage battery, and the nonlinear parameters include a full charge capacity.

37. The model parameter estimation device according to claim 36, wherein the state space model includes positive-electrode potential characteristic information representing a relationship between a positive-electrode electric quantity and a positive-electrode potential of the storage battery, and negative-electrode potential characteristic information representing a relationship between a negative-electrode electric quantity and a negative-electrode potential of the storage battery, and the nonlinear parameters include at least one of a positive-electrode capacity, a negative-electrode capacity, a positive-electrode electric quantity, and a negative-electrode electric quantity instead of the full charge capacity.

38. A model parameter estimation method comprising:
a step of setting initial values of nonlinear parameters of a state space model that represents a target system using the nonlinear parameters and linear parameters;
a state quantity calculation step of calculating state quantities indicating a state of the target system with respect to a measured value of an input on a basis of a state equation obtained by assigning values to the nonlinear parameters for the state space model, and time-series data of each of measured values of the input and an output of the target system;
a linear parameter estimation step of estimating the linear parameters that minimize an error between the measured value of the terminal voltage and an estimated value of the output calculated on a basis of the state space model, the state quantities, and the measured value of the input; and
a nonlinear parameter update step of updating the nonlinear parameters by repeatedly updating the values of the nonlinear parameters so as to make the minimized error to be small until a predetermined convergence condition is satisfied.

39. The model parameter estimation method according to claim 38, wherein in the step of setting the initial values, the initial values are set assuming that the target system is a storage battery, and in the state quantity calculation step, the state quantities are calculated assuming that the input is a current of the storage battery and the output is a terminal voltage of the storage battery.

40. The model parameter estimation method according to claim 38, wherein, in the nonlinear parameter update step, values of the nonlinear parameters are updated by using a gradient or a gradient approximate value of the estimated value of the terminal voltage with respect to the nonlinear parameters, or by using a gradient-free nonlinear optimization method.

41. The model parameter estimation method according to claim 39, wherein the nonlinear parameters include at least one of a state of charge, a full charge capacity, a diffusion time constant of the storage battery, and an offset current of a sensor used to measure the current, and the linear parameters include at least one of a DC resistance, a diffusion resistance, and a capacitor capacity of the storage battery.

42. The model parameter estimation method according to claim 38, wherein the state space model includes a linear equality constraint on the linear parameters, and in the linear parameter estimation step, the linear parameters are estimated by solving a linear least squares problem including the linear equality constraint by a method of Lagrange multiplier.

43. The model parameter estimation method according to claim 39, wherein the state space model includes OCV characteristic information representing a relationship between a state of charge and an open circuit voltage of the storage battery, and the nonlinear parameters include a full charge capacity.

44. The model parameter estimation method according to claim 43, wherein the state space model includes positive-electrode potential characteristic information representing a relationship between a positive-electrode electric quantity and a positive-electrode potential of the storage battery, and negative-electrode potential characteristic information representing a relationship between a negative-electrode electric quantity and a negative-electrode potential of the storage battery, and the nonlinear parameters include at least one of a positive-electrode capacity, a negative-electrode capacity, a positive-electrode electric quantity, and a negative-electrode electric quantity instead of the full charge capacity.
